(19) United States
(12) Patent Application Publication
(10) Pub. No.: US 2009/0114346 A1
(43) Pub. Date: May 7, 2009

(54) Substrate processing apparatus

(75) Inventors: Tsukasa Yashima, Imizu-shi (JP); Hiroshi Ekko, Toyama-shi (JP); Shigeki Nogami, Toyama-shi (JP); Isao Teranishi, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/289,688

(22) Filed: Oct. 31, 2008

(30) Foreign Application Priority Data
Nov. 5, 2007 (JP) 2007-287843
Oct. 1, 2008 (JP) 2008-256588

(51) Int. Cl. H01L 21/306

(52) U.S. Cl. 156/345.24

(57) ABSTRACT

To eliminate unrequited maintenance by re-executing the sequence that is the cause of an error in a substrate processing apparatus.

The system is provided with a processing chamber that processes a substrate, a carrier that carries the substrate, and a first controller that controls the carrier in accordance with a predetermined carrying sequence composed of a plurality of sequences, wherein if an error occurs while the carrier is carrying the substrate, after the first controller temporarily suspends an execution of the carrying sequence, it suspends the processing upon receipt of the stop processing and

re-executes the sequence that is the cause of the error occurrence out of the carrying sequence upon receipt of the retry processing.

### BACKGROUND OF THE INVENTION

1. Field of the Invention

The present invention relates to a substrate processing apparatus and particularly relates to a substrate processing apparatus including a controller that performs control in accordance with a predetermined sequence.

2. Description of the Related Art

In a conventional substrate processing apparatus, there is known a substrate processing apparatus including a processing chamber that processes a substrate, a carrying robot that carries the substrate, and a controller that controls the carrying robot in accordance with a predetermined carrying sequence composed of a plurality of sequences, for example, a cluster-type or in-line-type substrate processing apparatus. Such a substrate processing apparatus is provided with various sensors that automatically control the carrying robot.

### SUMMARY OF THE INVENTION

However, if an error occurs to issue an alarm in an automatic control, there may be a case where an unrequired maintenance time is taken until lot processing is resumed.

For example, when a wafer is unloaded from a chamber in a conventional vacuum carrying sequence, the existence/nonexistence of a wafer is detected by ON, OFF of a wafer existence/nonexistence detection sensor. In a normal case, the wafer existence/nonexistence detection sensor is turned ON, and in an abnormal case, the sensor is turned OFF to issue an alarm.

However, when a normal case or an abnormal case is judged by ON, OFF of the sensor, because whether a portion that is the cause of an error is the sensor or it is an apparatus side that is detected by the sensor can't be judged, a cause at a time when an alarm is issued can't be clearly identified. Therefore, even if an alarm is issued due to temporary malfunction of the sensor, as in part replacement or repairing after lot processing is suspended, a wafer is collected at a wafer carrier (FOUP), and the cause of the alarm is identified, thus taking vain time.

It is an object of the present invention to prevent the generation of an unrequired maintenance by re-executing the sequence that is the cause of an error.

One embodiment according to the present invention provides a substrate processing apparatus including a processing chamber that processes a substrate, a carrier that carries the substrate, and a first controller that controls the carrier in accordance with a predetermined carrying sequence composed of a plurality of sequences, wherein when an error occurs during carrying the substrate by the carrier, after the first controller temporarily suspends an execution of the carrying sequence, the first controller stops the processing upon receipt of stop processing and re-executes the sequence that is the cause of an error occurrence out of the carrying sequences upon receipt of retry processing.

Another embodiment according to the present invention provides a substrate processing apparatus including a processing chamber that processes a substrate, a carrier that carries the substrate, and a second controller that controls to process the substrate in accordance with a predetermined processing sequence composed of a plurality of sequences, wherein when an error occurs during processing the substrate in the processing chamber, after the second controller temporarily suspends an execution of the processing, the second controller stops the processing upon receipt of the stop processing and re-executes the step that is the cause of an error occurrence out of the processing sequences upon receipt of retry processing.

Another embodiment according to the present invention provides a substrate processing apparatus including a substrate accommodating section that loads a substrate accommodating container accommodating a plurality of substrates, an atmosphere carrying chamber that is communicated with the substrate accommodating container, a preliminary chamber that is communicated with the atmosphere carrying chamber and can vacuum-exhaust an inside of said preliminary chamber, a substrate processing chamber that is communicated with the preliminary chamber and processes the substrate, an atmosphere carrier that carries the substrate between the substrate accommodating container and the preliminary chamber, a vacuum carrier that carries the substrate between the preliminary chamber and the substrate processing chamber, and a first controller that controls operations of the atmosphere carrier or the vacuum carrier, wherein when an error occurs during carrying the substrate by the atmosphere carrier or the vacuum carrier, after the first controller temporarily suspends an execution of the carrying sequences, the first controller stops the processing upon receipt of the stop processing and re-processes the sequence that is the cause of an error occurrence out of the carrying sequences upon receipt of retry processing.

Another embodiment according to the present invention provides a substrate processing apparatus including a substrate accommodating section that loads a substrate accommodating container accommodating a plurality of substrates, an atmosphere carrying chamber that is communicated with the substrate accommodating container, a preliminary chamber that is communicated with the atmosphere carrying chamber and can vacuum-exhaust an inside of said preliminary chamber, a substrate processing chamber that is communicated with the preliminary chamber and processes the substrate, an atmosphere carrier that carries the substrate between the substrate accommodating container and the preliminary chamber, a vacuum carrier that carries the substrate between the preliminary chamber and the substrate processing chamber, a second controller that controls operations of the atmosphere carrier or the vacuum carrier, and a second controller that controls to process the substrate in accordance with a predetermined processing sequence composed of a plurality of steps, wherein when an error occurs during processing the substrate in the processing chamber, after the second controller temporarily suspends an execution of the processing sequence, the second controller stops the processing upon receipt of the stop processing and re-executes the step that is the cause of an error occurrence out of the processing sequences upon receipt of retry processing.

### BRIEF DESCRIPTION OF THE DRAWINGS

FIG. 1 is a schematic configuration diagram of a cluster-type semiconductor manufacturing apparatus of one embodiment according to the present invention;

FIG. 2 is a schematic configuration diagram of an in-line-type semiconductor manufacturing apparatus of one embodiment according to the present invention;

FIG. 3 is a block diagram of a controller provided by the semiconductor manufacturing apparatus of one embodiment according to the present invention;

FIG. 4 is a schematic diagram of an operation screen displayed by the controller provided in the semiconductor manufacturing apparatus of one embodiment according to the present invention;

FIG. 5 is a sequence diagram showing a substrate carrying sequence executed in the semiconductor manufacturing apparatus of one embodiment according to the present invention;

FIG. 6 is a sequence diagram showing a pressure judgment sequence in a vacuum lock chamber of a carrying sequence of one embodiment according to the present invention;

FIG. 7 is a sequence diagram showing a carrying destination gate valve opening sequence of the carrying sequence of one embodiment according to the present invention;

FIG. 8 is a sequence diagram showing a wafer unloading sequence of the carrying sequence of one embodiment according to the present invention;

FIG. 9 is a sequence diagram showing a wafer existence/nonexistence detection and wafer unloading sequence of the carrying sequence of one embodiment according to the present invention;

FIG. 10 is a sequence showing a wafer transferring sequence of the carrying sequence of one embodiment according to the present invention;

FIG. 11 is a sequence diagram showing a carrying destination gate valve closing sequence of the carrying sequence of one embodiment according to the present invention; and

FIG. 12 is a sequence diagram of a process recipe of one embodiment according to the present invention having at least a substrate loading step, a process preparation step, a process step, and a substrate unloading step.

### DETAILED DESCRIPTION OF THE PREFERRED EMBODIMENTS

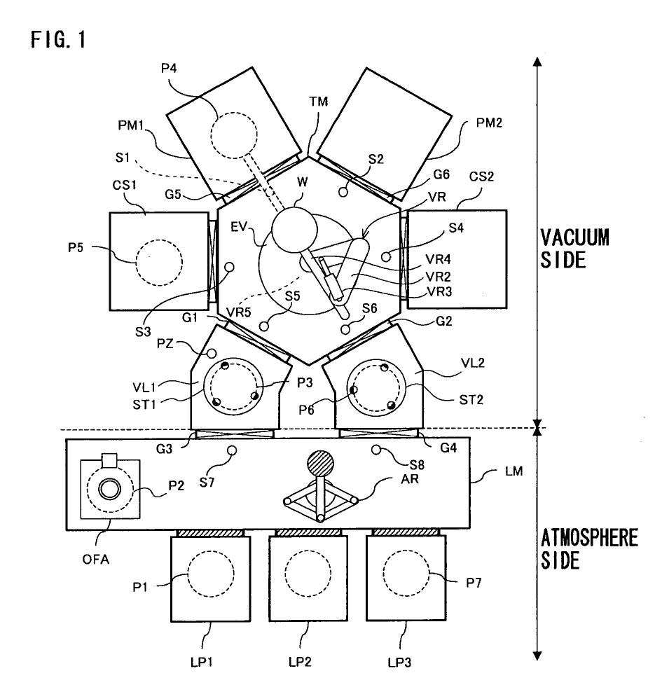

A substrate processing apparatus of one embodiment according to the present invention is described below with reference to FIG. 1 to FIG. 11.

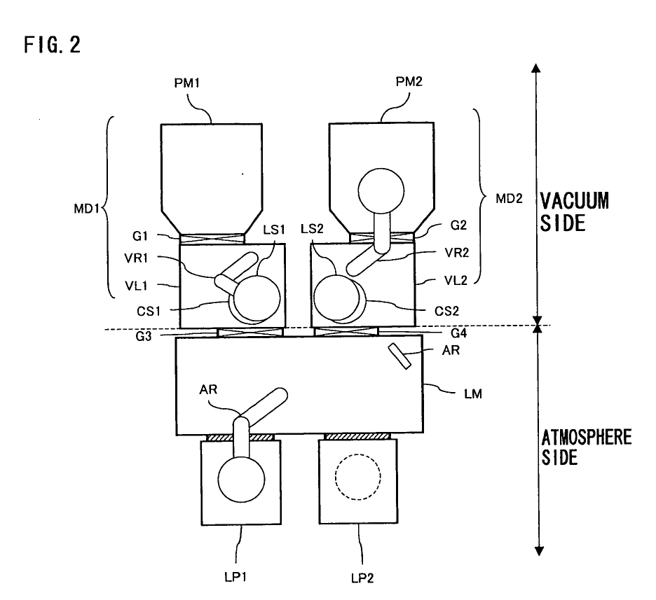

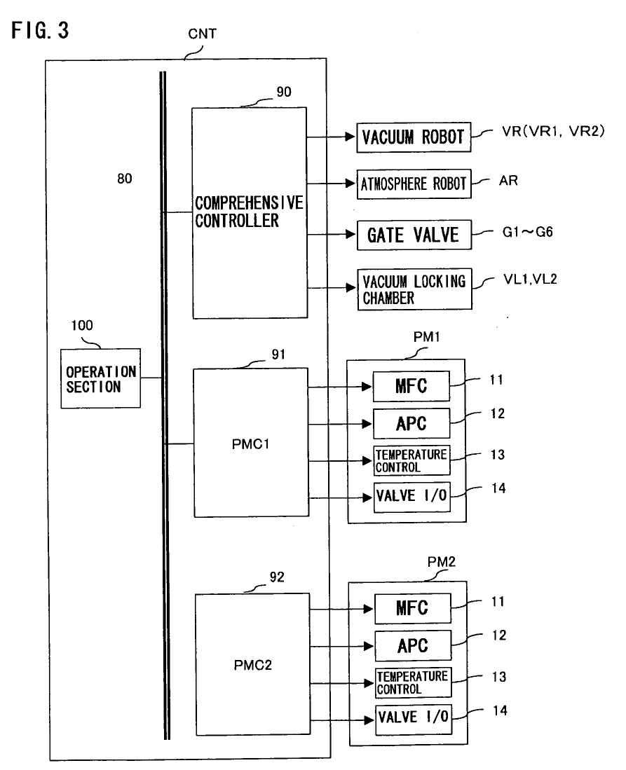

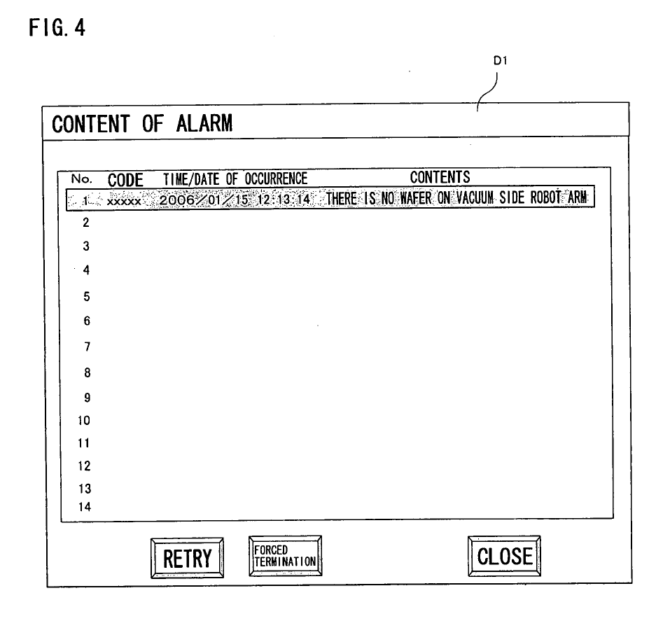

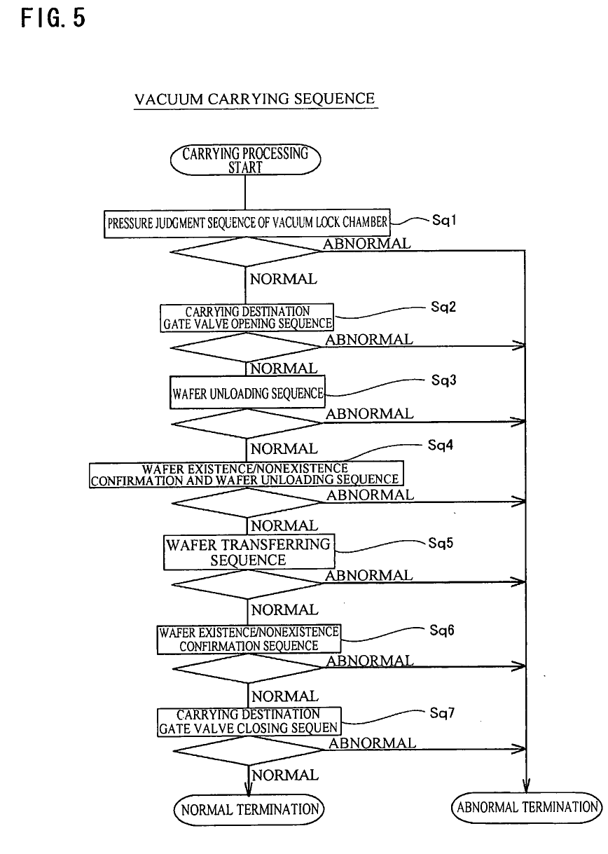

In the drawings which are referred to, FIG. 1 is a schematic configuration diagram of a cluster-type semiconductor manufacturing apparatus of one embodiment according to the present invention, FIG. 2 is a schematic configuration diagram of an in-line-type semiconductor manufacturing apparatus of one embodiment according to the present invention, FIG. 3 is a block diagram of a controller provided by the semiconductor manufacturing apparatus of one embodiment according to the present invention. In addition, FIG. 4 is a schematic diagram of an operation screen displayed by the controller provided by the semiconductor manufacturing apparatus of one embodiment according to the present invention, and FIG. 5 to FIG. 11 are each a flow chart of a substrate carrying sequence executed in the semiconductor manufacturing apparatus of one embodiment according to the present invention.

### (1) Configuration of Semiconductor Manufacturing Apparatus

Generally, a semiconductor manufacturing apparatus is classified into two types in accordance with a chamber arrangement. One is a cluster-type semiconductor manufacturing apparatus where a plurality of chambers are disposed around a carrying chamber in a star-shaped form. The other is an in-line-type semiconductor manufacturing apparatus where a chamber and a carrying chamber are each arranged on a straight line.

The configurations of the cluster-type semiconductor manufacturing apparatus and the in-line-type semiconductor manufacturing apparatus, and configurations of a controller that controls these apparatuses are described below with reference to FIG. 1, FIG. 2 and FIG. 3, respectively.

### (1-1) Configuration of Cluster-Type Semiconductor Manufacturing Apparatus

FIG. 1 is a schematic configuration example of a cluster-type semiconductor manufacturing apparatus of one embodiment according to the present invention.

The cluster-type semiconductor manufacturing apparatus is divided into a vacuum side and an atmosphere side.

### (a) Configuration of Vacuum Side

A vacuum carrying chamber TM that can be vacuum-tight, vacuum lock chambers VL1, VL2 each having a preliminary chamber, process chambers PM1, PM2 each having a substrate processing chamber, and cooling chambers CS1, CS2 are provided on the vacuum side of the cluster-type semiconductor manufacturing apparatus. The vacuum lock chambers VL1, VL2, process chambers PM1, PM2, and cooling chambers CS1, CS2 are disposed in star-shaped form at a circumference of the vacuum carrying chamber TM.

The vacuum carrying chamber TM is configured in a load lock chamber structure that can withstand a pressure of less than the atmospheric pressure (negative pressure) such as vacuum. In addition, in one embodiment of the present invention, the body of the vacuum carrying chamber TM is formed in a box-type that is a hexagon in plan view and whose upper and lower ends are closed on both ends.

The vacuum carrying chamber TM is provided with a vacuum side robot VR as a vacuum carrier.

The vacuum side robot VR is installed on an elevatable elevator EV and includes a rotary section VR5 that is rotated around a vertical axis, a folding link VR2 foldably provided along a horizontal plane to the rotary section VR5, a cylinder VR3 that is strid over the folding link VR2 and controls stretching and folding of the folding link VR2 with its expansion, and an arm VR 4 that is attached to the folding link VR2 and is slide-moved between a home position of the rotary section VR5 and a wafer loading position in the radial direction outside with its folding.

Thus, the vacuum side robot VR can be elevated, can be rotated, and can be stretched, and is designed to transfer a wafer W between the vacuum lock chambers VL1, VL2, process chambers PM1, PM2, and cooling chambers CS1, CS2 with their cooperation.

In addition, wafer existence/nonexistence detection sensors S1, S2, S3, S4, S5, and S6 are provided to detect the existence/nonexistence of a wafer W on the arm VR4 on the forward/backward tracks of the arm VR4 before the vacuum lock chambers VL1, VL2, process chambers PN1, PM2, and cooling chambers CS1, CS2.

In addition, a wafer loading section at the tip of the arm VR4, even if not illustrated, is formed in a crotch fork to detect the existence/nonexistence of a wafer W with the wafer existence/nonexistence detection sensors S1, S2, S3, S4, S5, and S6.

The substrate processing chamber that gives added values such as, for example, depositions with thermal reaction (CVD) to the wafer W is configured inside the process chambers PM1, PM2.

In addition, the process chambers PM1, PM2 are provided with a gas introduction/exhaust mechanism (not illustrated) and a plasma discharge mechanism (not illustrated), a mass-flow controller (MFC)11 that controls a flow of processing gas that is supplied into the process chambers PM1, PM2, an automatic pressure controller (APC) 12 that controls pressures in the process chambers PM1, PM2, a temperature controller 13 that controls temperatures in the process chambers PM1,PM2, an inlet/outlet valve I/O14 that controls ON/OFF of an exhaust valve or supply of the processing gas, and the like.

The insides of the vacuum lock chambers VL1, VL2 are used as the preliminary chambers that load the wafer W into the vacuum chamber TM or as the preliminary chambers that unload the wafer W from the vacuum lock chamber TM. The vacuum lock chambers VL1. VL2 are provided with buffer stages ST1, ST2 that temporarily support the wafer W.

The insides of the vacuum lock chambers VL1, VL2 are each communicated with the vacuum carrying chamber TM through gate valves G3, G4, and are also each communicated with the atmosphere carrying chamber LM later described through gate valves G1, G2. Therefore, the wafer W can be carried between the vacuum lock chambers VL1, VL2 and the atmosphere carrying chamber LM, with vacuum-tightness in the vacuum carrying chamber TM kept, by opening the gate valves G3, G4 with the gate valves G1, G2 closed.

In addition, because the vacuum lock chambers VL1, VL2 are formed of a load lock chamber structure that can withstand a negative pressure of less than the atmospheric pressure such as vacuum, and each inside can be vacuum exhausted. Therefore, the wafer W can be carried between the vacuum lock chambers VL1, VL2 and vacuum carrying chamber TM with vacuum in the vacuum carrying chamber TM kept, by opening the gate valves G3, G4 after the gate valves G3, G4 are closed and the insides of the vacuum lock chambers VL1, VL2 are vacuum-exhausted.

The cooling chambers CS1, CS2 function to accommodate and cool the wafer W. The insides of the cooling chambers CS1, CS2 are designed to be able to be vacuum-exhausted.

### (b) Configuration of Atmosphere Side

On the other hand, the atmosphere carrying chamber LM connected to the vacuum lock chambers VL1, VL2 and the load ports LP1 to LP3 as the substrate accommodating section that loads the substrate accommodating containers (hereinafter referred to as pads PD1 to PD3) connected to the atmosphere carrying chamber LM are provided on the atmosphere side of the cluster-type semiconductor manufacturing apparatus, as above-mentioned.

The atmosphere carrying chamber LM is provided with a clean air unit, even if not illustrated, that feeds clean air into the inside of the atmosphere carrying chamber LM.

The atmosphere carrying chamber LM is provided with one atmosphere side robot AR as the atmosphere carrier. The atmosphere side robot AR mutually carries the wafer W between the vacuum lock chambers VL1, VL2 and load ports LP1 to LP3. The atmosphere side robot AR is also configured as in the vacuum side robot VR.

In addition, the wafer existence/nonexistence detection sensors S7, S8 are also installed at predetermined positions before the atmosphere carrying chamber LM (for example, in the vicinity of the gate valve) likewise, it is designed to be able to detect whether or not a wafer W is loaded on the wafer loading section at the tip of the arm VR4 with the wafer existence/nonexistence detection sensors S7, S8, i.e. the existence/nonexistence of a wafer W, as described later.

In addition, the atmosphere carrying chamber LM is provided with an orientation flat aligning apparatus OFA that performs the positioning of crystal orientation in the wafer W and the like as a substrate position correcting apparatus.

Load ports LP1 to LP3 can load the pods PD1 to PD3 (not illustrated) that can accommodate a plurality of wafers W, respectively.

### (c) Configuration of Controller

Each component section of the cluster-type semiconductor manufacturing apparatus is controlled by a controller CNT.

A configuration example of the controller CNT is shown in FIG. 3. The controller CNT is provided with a comprehensive controller 90, process chamber controllers PM1, PM2, and an operation section 100, and these apparatuses are connected so as to allow data to be mutually exchanged with a LAN line 80.

The comprehensive controller 90 is connected to the vacuum side robot VR, atmosphere side robot AR, gate valves G1 to G4, and the vacuum exhaust system and atmosphere introduction system of the vacuum lock chambers VL1, VL2, respectively. Then, the comprehensive controller 90 controls the operations of the vacuum side robot VR and atmosphere side robot AR, opening/closing operations of the gate valves G1 to G4, and vacuum exhaust system and atmosphere introduction system inside the vacuum lock chambers VL1, VL2.

The process chamber controllers PM1, PM2 are connected to the MFC 11, automatic pressure controller (APC) 12, temperature controller 13, I/O 14 and the like provided at the process chambers PM1, PM2, respectively. Then, the process chamber controllers PM1, PM2 are designed to control each operation of the gas introduction to the process chambers PM1, PM2/exhaust mechanism therefrom, temperature control/plasma discharge mechanism of the process chambers PM1, PM2, cooling mechanism of the cooling chambers CS1, CS2 and the like.

The operation section 100 covers screen displays and input receipt functions such as instructions of system control commands, monitor displays, logging data, alarm analyses, and parameter editions.

### (1-2) Configuration of In-Line Type Semiconductor Manufacturing Apparatus

Subsequently, a configuration example of the in-line type semiconductor manufacturing apparatus of one embodiment according to the present invention is shown in FIG. 2. The in-line-type semiconductor manufacturing apparatus is also divided into the vacuum side and atmosphere side.

### (a) Configuration of Vacuum Side

Two substrate processing modules MD1, MD2 are provided in parallel on the vacuum side of the in-line-type semiconductor manufacturing apparatus. The substrate processing module MD1 is provided with the process chamber PM1 comprising a substrate processing chamber that is in-line connected and can be vacuum-tight, and the vacuum lock chamber VL1 comprising a preliminary chamber that can be vacuum-tight provided in the front stage. The substrate processing module MD2 is provided with the process chamber PM2 and vacuum lock chamber VL2 as in MD1.

The insides of the process chambers PM1, PM2 function as the substrate processing chambers that each give an added value such as, for example, depositions with chemical reaction (CVD) to the wafer W as in the cluster-type semiconductor manufacturing apparatus. Then, the process chambers PM1, PM2 are provided with the gas introduction/exhaust mechanism, and temperature control/plasma discharge mechanism, mass flow controller (MFC) 11 that controls a flow of the processing gas supplied into the process chambers PM1, PM2, automatic pressure controller (APC)12 that controls pressures in the process chambers PM1, PM2, temperature controller 13 that controls temperatures in the process chambers PM1, PM2, input/output valve I/O 14 that controls ON/OFF of the supply or exhaust valve of the processing gas, and the like.

The vacuum lock chambers VL1, VL2 each function as the preliminary chamber that loads the wafer W into the process chambers PM1, PM2 or as the preliminary chamber that unloads the wafer W from the process chambers PM1, PM2.

The vacuum lock chambers VL1, VL2 are provided with the vacuum side robots VR1, VR2 as the second substrate carrying apparatuses. The vacuum side robots VR1, VR2 can carry the wafer W between the process chamber PM1 and vacuum lock chamber VL1 and between the process chamber PM2 and vacuum lock chamber VL2. In addition, these vacuum side robots VR are each provided with the arm VR4 having the substrate loading section.

In addition, the vacuum lock chambers VL1, VL2 are provided with a multi-step stage that can hold the wafer W, for example, an upper/lower two-stepped stage.

The upper-stepped buffer stages LS1, LS2 are provided with apparatuses that hold the wafer W and the lower-stepped cooling stages CS1, CS2 are provided with apparatuses that cool the wafer W.

The vacuum lock chambers VL1, VL2 are each communicated with the process chamber controllers PMC1, PMC2 through the gate valves G1, G2 and are each communicated with the atmosphere carrying chamber LM later described through the gate valves G3, G4.

Therefore, the wafer W can be carried between the vacuum lock chamber VL1 and the process chamber controller PMC1 and between the vacuum lock chamber VL2 and the process chamber controller PMC2, with vacuum-tightness in the process chamber controller PMC1, PMC2 kept by opening the gate vales G3, G4 with the gate valves G1, G2 closed.

In addition, the vacuum lock chambers VL1, VL2 are configured as the load lock chamber structure that can withstand a negative pressure of less than the atmospheric pressure such as vacuum, and the insides of the vacuum lock chambers can be vacuum-exhausted.

Therefore, the wafer W can be carried between the vacuum lock chambers VL1, VL2 and the atmosphere carrying chamber LM, with vacuum-tightness in the process chamber controllers PMC1, PMC2 kept by opening the gate valves G1, G2 after the gate valves G3, G4 are closed and the insides of the vacuum lock chambers VL1, VL2 are vacuum-exhausted.

In addition, the vacuum side robots VR1, VR2 are provided with a rotational position detection sensor (not illustrated) that detects a rotational position of the rotary section VR5 as required and a cylinder stroke sensor (not illustrated) that detects a position of a wafer loading section at the tip of the arm VR4 with an extension stroke of the cylinder VR3, and the elevator EV is provided with an elevating position detection sensor that detects an elevating position of the elevator EV.

The elevating position detection sensor detects the elevating position of the wafer loading section accordingly by detecting a height of the elevator EV with a height position detection sensor (not illustrated).

### (b) Configuration of Atmosphere Side

The atmosphere carrying chamber LM connected to the vacuum lock chambers VL1, VL2 and load ports LP1, LP2 as the substrate accommodating sections that load the substrate accommodating containers (hereinafter referred to as pods PD1, PD2) connected to the atmosphere carrying chamber LM are provided on the atmosphere side of the in-line-type semiconductor manufacturing apparatus, as above-mentioned.

The atmosphere carrying chamber LM is provided with the atmosphere side robot AR, and the wafer W can be carried between the vacuum lock chambers VL1, VL2 and load ports LP1, LP2. In addition, the atmosphere side robot AR is provided with an arm as the substrate loading section.

In addition, the atmosphere carrying chamber LM is provided with an aligner unit AU as a substrate position correcting apparatus that allows the system to correct a deviation of the wafer W at the time of carrying the wafer W and perform notch-alignment that aligns the notch of the wafer W in a certain direction.

The load ports LP1, LP2 can load the pods PD1, PD2 (not illustrated) that accommodate a plurality of wafers W, respectively.

### (c) Configuration of Controller

Each component section is controlled by the controller CNT.

A configuration example of the controller is shown in FIG. 3. The controller CNT is provided with the comprehensive controller 90, process chamber controllers PMC1, PMC2, and operation section 100, and these apparatuses are connected so as to allow data to be mutually exchanged with the LAN line 80.

The comprehensive controller 90 is connected to the vacuum side robots VR1, VR2, atmosphere side robot AR, gate valves G1 to G4, and vacuum lock chambers VL1, VL2, respectively. In addition, the comprehensive controller 90 controls the operations of the vacuum side robot VR and atmosphere side robot AR, opening/closing operations of the gate valves G1 to G4, and exhaust operation inside the vacuum lock chambers VL1, VL2.

The process chamber controller PMC1, PMC2 are connected to the MFC 11, automatic pressure controller (APC) 12, temperature controller 13, I/O 14, and the like provided at the process chambers PM1, PM2, respectively. In addition, the process chamber controllers PMC1, PMC2 control each operation of the gas introduction to the process chambers PM1, PM2/exhaust mechanism therefrom, temperature control/plasma discharge mechanism thereof, cooling mechanism of the cooling chambers CS1, CS2, and the like.

The operation section 100 covers screen display/input receipt function such as instructions of system control commands, monitor displays, logging data, alarm analyses, and parameter editions.

### (2) Summary of Automatic Carrying Processing (Substrate Carrying Sequence)

Next, the summary of the automatic wafer W carrying processing performed by the above-mentioned cluster-type semiconductor manufacturing apparatus is described with reference to FIG. 1. In addition, the operations of each section of the semiconductor manufacturing apparatus shall be controlled by the controller CNT in the description below.

(2-1) Loading Pod onto Load Port

First, the gate valves G1, G4 are closed, and the gate valves G2, G4 are opened, next, whether or not the opening/closing the gate valves G2, G3 is normal is judged. If a judgment result is normal, the insides of the vacuum carrying chamber TM, process chambers PM1, PM2, and cooling chambers CS1, CS2 are vacuum-exhausted. At the same time, clean air is supplied into the atmosphere carrying chamber LM so as to be almost the atmospheric pressure. Then, the pod PD1 (not illustrated) where a plurality of unprocessed wafers W are accommodated is loaded on the load port LP1.

### (2-2) Carrying Wafer W to Atmosphere Carrying Chamber

Subsequently, the wafer W accommodated at a substrate position P1 inside the pod PD1 loaded on the load port LP1 is carried into the atmosphere carrying chamber LM, is installed at a substrate position P2 on the orientation flat apparatus OFA, and positioning of crystal orientation, and the like are performed with the atmosphere side robot AR.

### (2-3) Carrying Wafer W to Vacuum Lock Chamber

Subsequently, the wafer W installed at the substrate position P2 is picked up, is carried into the vacuum lock chamber VL1, and is installed at a substrate position P3 on the buffer stage ST1 with the atmosphere robot AR. Then, the gate valve G3 is closed to vacuum-exhaust the inside of the vacuum lock chamber VL1.

### (2-4) Carrying Wafer W to Process Chamber

If the vacuum lock chamber VL1 is depressurized up to a predetermined pressure, the gate valve G1 is opened with the gate valve G3 closed. Then, the wafer W installed at the substrate position P3 is picked up, is carried into the process chamber PM1, and is installed at a substrate position P4 with the vacuum side robot VR1. Thereafter, a processing gas is fed into the process chamber PM1 to perform predetermined processing on the wafer W.

### (2-5) Carrying Wafer W to Cooling Chamber

If the processing on the wafer W is completed inside the process chamber PM1, the processed wafer W installed at the substrate position P4 is picked up, is carried into the cooling chamber CS1, and is installed at a substrate position P5 with the vacuum side robot VR.

### (2-6) Carrying Wafer W to Vacuum Lock Chamber

If the cooling processing is completed inside the cooling chamber CS1, the processed wafer W installed at the substrate position P5 is picked up, is carried into the vacuum lock chamber VL2, and is disposed at a substrate position P6 on the buffer stage ST2 with the vacuum side robot VR. Thereafter, the gate valve G2 is closed, a clean gas is fed into the vacuum lock chamber VL2 to get the vacuum lock chamber VL2 back to almost the atmospheric pressure and the gate valve G4 is opened.

(2-7) Accommodation of Wafer W into Pod Loaded on Load Port

Subsequently, the processed wafer W installed at the substrate position P2 is picked up, is carried into the pod PD3 (not illustrated) loaded on the load port LP3, and is accommodated into a vacant slot with the atmosphere side robot AR.

Thereafter, after the above-mentioned process is repeated to perform automatic carrying processing on all unprocessed wafers W, the pod PD3 where the processed wafers W are accommodated is unloaded from the load port LP3 to complete the automatic carrying processing.

### (3) FIG. 5 Shows One Example of the Vacuum Carrying Sequence of a Wafer W of the Present Invention.

In addition, the vacuum carrying sequence is a carrying sequence in a vacuum atmosphere that is executed to carry a wafer W in the processes (2-3) to (2-6) that are a part of the above-mentioned automatic carrying sequences in the embodiment. These sequences are executed with the controller CNT.

As shown in FIG. 5, the pressure judgment sequence of the vacuum lock chamber Sq1, carrying destination gate valve opening sequence Sq2, wafer unloading sequence Sq3, wafer existence/nonexistence confirmation and wafer unloading sequence Sq4, wafer transferring sequence Sq5, wafer existence/nonexistence confirmation sequence Sq6, and carrying destination gate valve closing sequence Sq7 are executed in this order in the vacuum carrying sequence of the embodiment.

If an error occurs in each sequence to issue an alarm, the vacuum carrying sequence is temporarily suspended, then, retry processing or abnormal termination processing is selected by a maintenance worker.

The retry processing is processing that confirms whether or not the error is cancelled to restore the system by re-executing the sequence that is the cause of the error, the abnormal termination processing is processing that terminates the vacuum carrying sequence if an error cancellation can't be expected to restore the system and allows maintenance to be executed. In addition, the number of retry processing may be subjected to a judgment of the maintenance worker or may be designated in advance.

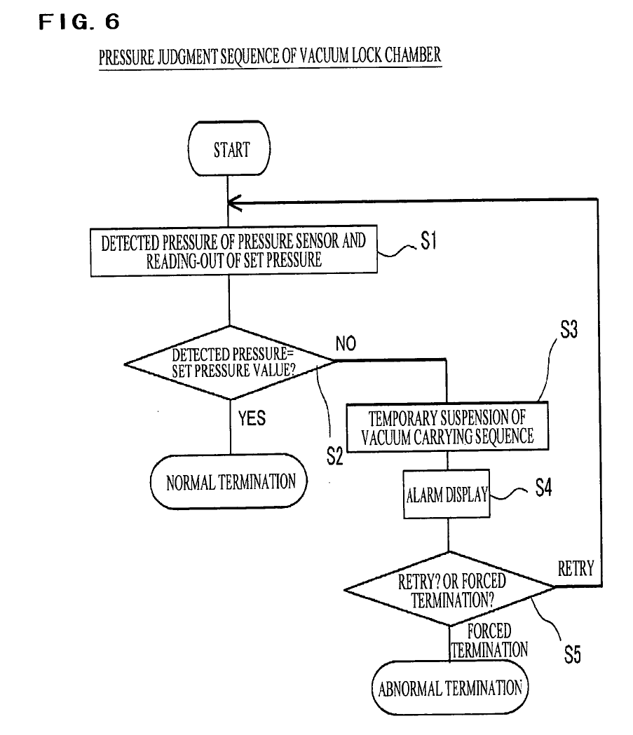

The details of each sequence Sq1 to Sq9 shown in FIG. 5 are described below with reference to FIG. 6 to FIG. 11. In addition, with regard to the vacuum carrying sequence, a sequence that carries a wafer W between the other vacuum lock chamber VL2 and cooling chamber CS2, a sequence that carries a wafer W between one process module VL1 and cooling chamber CS1 and the other process module VL2 and cooling chamber CS1, and the like are provided in addition to a sequence that carries a wafer W between one vacuum lock chamber VL1 and process chamber PM1, these sequences are executed. However, for these sequences, only carrying origin and carrying destination are different and the procedures of carrying are reverse in the embodiment. Therefore, the vacuum carrying sequence between the vacuum lock chamber VL1 and process chamber PM1 is described and the descriptions of other sequences are omitted in the embodiment.

### (3-1) Pressure Judgment Sequence of Vacuum Lock Chamber (Sq1)

FIG. 6 shows one example of the pressure judgment sequence Sq1 of the vacuum lock chamber.

This sequence Sq1 is a sequence that confirms whether or not the pressure of the vacuum lock chamber VL1 is the same as in the vacuum carrying chamber TM before the wafer W is carried from the vacuum lock chamber VL1 to the vacuum carrying chamber TM.

In this sequence Sq1, first, a pressure sensor that detects a pressure of the vacuum lock chamber VL1, namely, reads out a detected pressure value of the vacuum gage PZ and a set pressure value (Step S1), next, whether or not the detected pressure of vacuum gage PZ is the same as the set pressure is judged (Step S2).

If a judgment result is NO, an error occurs to issue an alarm.

If the alarm is issued, the vacuum carrying sequence is temporarily suspended (Step S3), subsequently, the alarm is displayed on an operation screen by transmitting the alarm display that is the result of the error onto a monitor (Step S4). This allows the alarm result to be noticed to a maintenance worker.

The alarm display, for example, as shown in FIG. 4, includes an error data showing the content of an error that is the cause of an alarm occurrence and an error processing button that processes the error, and the error data includes at least date that identifies a kind or a content of the alarm.

In an illustrated example, an example such that the error data includes the content of the error, code (error code), and time/date of occurrence is shown. However, in addition to this example, a supplementary data that identifies or captures an error (for example, an instruction for the details of maintenance) may be displayed.

For the error processing buttons, the “retry” button and the “forced termination” button are displayed.

The “retry” button is a button that re-executes retry processing, namely, processing of the sequence that is the cause of an error occurrence, and the “forced termination” button is a button that suspends the vacuum carrying processing and abnormally terminates the vacuum carrying sequence.

If a maintenance worker selects the “retry” button in Step S5 in FIG. 6, the retry processing that executes the sequences after Step S1 that are the cause of an error occurrence is executed.

In case of the pressure judgment sequence Sq1 of the vacuum lock chamber VL1, malfunction of the controller CNT, malfunction or failure of the vacuum gage PZ, defective operations of the gate valve G3, and defective sealing of the vacuum system or atmosphere introduction system in the vacuum lock chamber VL1 are considered as causes of the error occurrence.

If the retry processing is performed, an error caused by temporary malfunction of the pressure gage PZ or the controller CNT is cancelled to restore the system. However, other errors may be also cancelled to restore the system if retry processing is repeated several times. Therefore, whether or not maintenance is required can be correctly judged by executing the retry processing.

If an error is not cancelled to restore the system even if the retry processing is executed, or if a restoration is hard from the viewpoint of the error item name or content of an alarm display, the “forced termination” button is selected by a maintenance worker in Step S5. If the “forced termination” button is selected, abnormal termination processing that abnormally terminates the carrying sequence is executed, thereafter, maintenance is executed.

In case of the abnormal termination, failure of the vacuum gage PZ, and defective operation or defective sealing of the gate valve G3, vacuum exhaust system or atmosphere introduction exhaust system are exemplified as the causes of an error, light errors that can be cancelled to restore the system by the retry processing, for example, temporary malfunction of the vacuum gage PZ is excluded from the objects of the maintenance.

Because the cause of an error is already narrowed even if the maintenance is executed, a maintenance time is more shortened than in a conventional method, thereby resulting in shortening a restoration time of the system.

If it is Yes and an error is cancelled to restore the system in Step S2, because a detected pressure value is equal to a set pressure value, this sequence Sq1 is normally terminated to proceed to the next carrying destination gate valve opening sequence Sq2.

### (3-2) Carrying Destination Gate Valve Opening Sequence (Sq2)

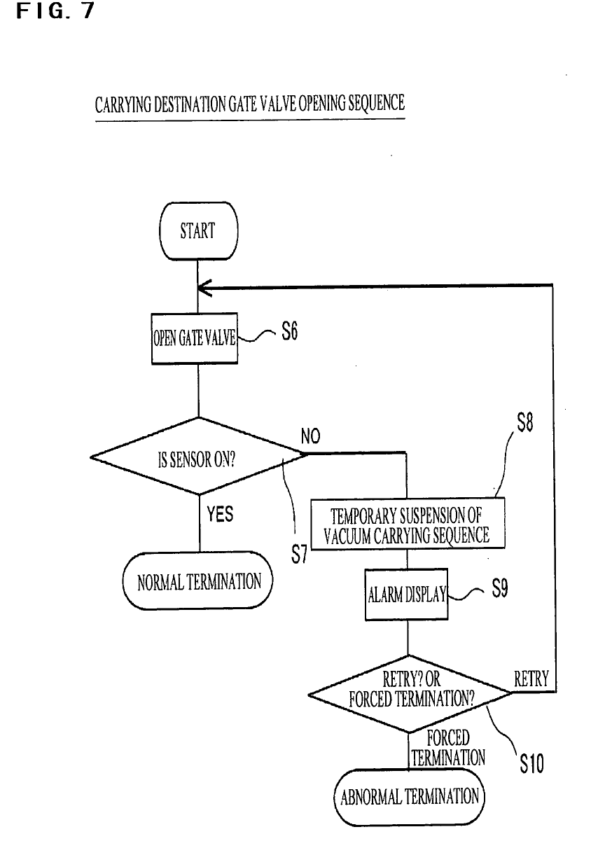

FIG. 7 shows one example of the carrying destination gate valve opening sequence Sq2.

This sequence Sq2 is a sequence that opens the gate valve G5 of the process chamber PM1 to carry the wafer W to a carrying destination that is the process chamber PM1 in this example.

In this sequence Sq2, first, after the gate valve G5 of the process chamber PM that is the carrying destination of the wafer W is opened (Step S6), whether or not the gate valve G5 is opened by ON, OFF of an opening/closing sensor that detects the opening/closing of the gate valve G5 is judged (Step S7).

If a judgment result is NO in a judgment in Step S7, namely, the opening/closing sensor is OFF, the sequence Sq2 is in error to issue an alarm.

If the alarm is issued, the vacuum carrying sequence is temporarily suspended (Step S8), and an alarm display is displayed on the operation screen D1 (Step S9). In this status, it is an instruction waiting from a maintenance worker.

If the maintenance worker presses a “retry” button (Step S10), the retry processing is executed and the sequences after Step S6 that are the causes of the error are re-executed.

If the error is cancelled to restore the system by the retry processing, the opening/closing sensor is turned ON and the opening of the gate valve G3 is detected.

As the causes of the error, malfunction or failure of the operating circuit in the gate valve G3, malfunction of the controller CNT, malfunction, failure or deviation of a mounting position of the opening/closing sensor are exemplified.

If the gate valve G3 is opened, the wafer W can be loaded between the process chamber PM1 and one vacuum lock chamber VL1.

If the error is not cancelled to restore the system or an error cancellation is not expected to restore the system by even the retry processing, the “forced termination” button is pressed on the operation screen D1, abnormal termination processing that forcedly suspends the vacuum carrying sequence is executed (Step S10).

If the vacuum carrying sequence is abnormally terminated, maintenance that cancels the error to restore the system is executed. In this case, as the causes of the error, deviation of a mounting position or failure of the opening/closing sensor, defective operation of the operation circuit in the gate valve G3, and the like are exemplified, excluding errors that may be cancelled to restore the system by the retry processing, namely, temporary malfunction.

As the maintenance, confirmation, modification or replacement of a mounting position of the opening/closing sensor, and inspection or replacement of the gate valve G3 are performed.

If a judgment result in Step S7 is normal, the next wafer unloading sequence Sq3 is executed.

### (3-3) Wafer Unloading Sequence (Sq3)

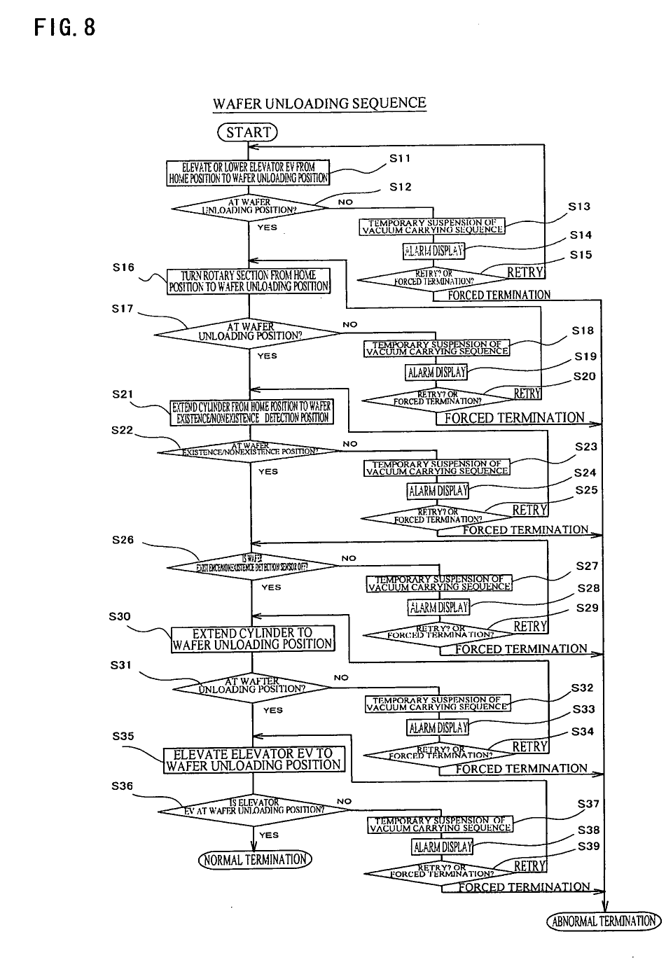

FIG. 8 shows one example of the wafer unloading sequence Sq3.

This sequence Sq3 is a sequence before the wafer W is unloaded from the vacuum lock chamber VL1 to the vacuum carrying chamber TM and is a sequence that unloads the wafer W being carried to the process chamber PM1 from the vacuum lock chamber VL1.

In this sequence Sq3, first, an elevating position of the vacuum side robot VR is controlled to an unloading position of the wafer W by elevating or lowering from a home position of the elevator EV (Step S11).

Thereafter, whether or not a height of the elevator EV is at a wafer W unloading position by comparing a detected value of the elevating position detection sensor (not illustrated) that detects an elevating position of the elevator EV with a set value (Step S12).

If a judgment result is NO, an error occurs to issue an alarm.

If the alarm is issued, the vacuum carrying sequence is temporarily suspended (Step S13), an alarm display is displayed on the operation screen D1 (Step S14).

As the causes of the error, mechanical or electrical failure of the elevator EV, or temporary malfunction of the elevating position detection sensor, temporary malfunction, failure or deviation of a mounting position of the controller CNT are exemplified.

In order to process and confirm an error, if the “retry” button is pressed (Step S15), the retry processing is executed, the sequences after Step S11 that are the causes of the error are re-executed.

As errors that can be cancelled to restore the system by the retry processing, for example, malfunction of the elevator EV, temporary malfunction of the controller CNT or temporary malfunction of the elevating position detection sensor, mechanical or electrical failure of the elevator EV, or failure of the elevating position detection sensor or deviation of a mounting position of the elevating position detection sensor, and the like are exemplified.

If the error can't be cancelled to restore the system by even the retry processing or an error cancellation can't be expected to restore the system from the viewpoint of contents or item name of the alarm display, the “forced termination” button is selected on the operation screen D1.

If the “forced termination” button is pressed, abnormal termination processing that forcedly suspends the vacuum carrying sequence is executed (Step S15).

If the vacuum carrying sequence is abnormally terminated, maintenance that cancels an error to restore the system is executed. In this case, as the causes of the error, mechanical or electrical failure of the elevator EV, or failure of the elevating position sensor or deviation of a mounting position of the elevating position sensor, and the like are exemplified, excluding malfunction of the elevator EV and temporary malfunction of the controller CNT or temporary malfunction of the elevating position sensor.

As the maintenance, repairing or replacement of the elevator EV, confirmation of a mounting position of the sensor or modification of a mounting position of the sensor are performed.

If a judgment result is normal in Step S12, the sequence proceeds to Step S16.

In Step S16, the rotary section VR5 is turned from the home position to the wafer unloading position, next, whether or not a turning angle of the rotary section VR5 is equal to that of the wafer unloading position is judged by comparing a detected turning angle by a rotational position detection sensor (not illustrated) provided at the rotary section VR5 with a set turning angle (Step S17).

If a judgment is NO in Step S17, an error occurs to issue an alarm.

If the alarm is issued, the vacuum carrying processing is temporarily suspended (Step S18), and an alarm display is displayed on the operation screen D1 (Step S19).

As the causes of the error, temporary malfunction of the rotational position detection sensor, temporary malfunction of the controller, failure of the rotary section VR5, failure of the rotational position detection sensor, deviation of the rotary section VR5 and the like are exemplified.

Thereafter, if a maintenance worker presses the “retry” button on the operation screen D1 (Step S20), the retry processing is executed and the sequences after Step S16 that are the causes of the error are re-executed.

As errors that are cancelled to restore the system by the retry processing, temporary malfunction of the rotational position detection sensor and temporary malfunction of the controller CNT are exemplified.

If the “forced termination” button is selected in Step S20, abnormal termination processing that suspends the carrying sequence is executed.

If the vacuum carrying sequence is abnormally terminated, the maintenance that cancels an error to restore the system is executed. In this case, as the cause of the error, failure or deviation of the rotary section VR5, failure of the rotational position detection sensor, and the like are exemplified, as the maintenance, repairing or replacement of the rotary section VR5, replacement of the rotational position detection sensor or modification of a mounting position thereof are performed.

If a judgment result is YES in Step S17 or the error is cancelled to restore the system by the retry processing, the next Step S21 is automatically executed.

In Step S21, the cylinder VR3 of the vacuum side robot VR is extended from the home position to the wafer existence/nonexistence detection position to detect whether or not the wafer W is loaded.

If the extension of the cylinder VR3 is finished, next, whether or not the wafer loading section at the tip section of the arm VR4 is extended to the wafer existence/nonexistence detection position that detects a wafer W existence/nonexistence is judged by comparing a detected value of the cylinder stroke sensor that detects an expansion/contraction position of the cylinder VR3 with a set value (Step S22).

If a judgment result is NO, an error occurs to issue an alarm.

If the alarm is issued, the vacuum carrying sequence is temporarily suspended (Step S23), and an alarm display is displayed on the operation screen D1 (Step S24).

As the causes of the error, deviation of a mounting position or defective operation of the cylinder VR3, failure of a mechanism for extension/contraction or failure of the circuit, temporary malfunction, failure or deviation of a mounting position of the cylinder stroke sensor, temporary malfunction of the controller CNT, and the like are exemplified.

If the “retry” button is selected on the operation screen D1 to process the error (Step S25), the retry processing is executed, and the sequences after Step S21 that are the causes of the error are re-executed.

As errors that are cancelled to restore the system by the retry processing, for example, there are temporary malfunction of the controller CNT, temporary malfunction of the cylinder stroke sensor, and the like. However, if the retry processing is repeated on errors other than these errors, they may be cancelled to restore the system.

If the error can't be cancelled to restore the system even if the “retry” processing is selected by the “retry” button or an error cancellation can't be expected to restore the system from the viewpoint of the content or item name of an alarm display, the “forced termination” button is pressed on the operation screen D1 (Step S25), and abnormal termination processing that terminates the carrying sequence is executed.

After the abnormal termination is over, the maintenance is executed. In this case, as the causes of the error, defective operation, failure of mechanism for expansion or the circuit of the cylinder VR3, deviation of a mounting position of the cylinder VR3, failure or deviation of a mounting position of the cylinder stroke sensor, and the like are exemplified.

As the maintenance, replacement or repairing of the cylinder VR3, mounting position of the cylinder stroke sensor or modification of a mounting position of the cylinder VR3 are performed.

If a judgment result in Step S22 is YES or an error is cancelled to restore the system by the retry processing, the sequence proceeds to the next Step S26 on the supposition that the processing is normally terminated.

In Step S26, whether or not the wafer W is loaded on the wafer loading section at the tip of the arm VR4 in the vacuum side robot VR is confirmed by ON, OFF of the wafer existence/nonexistence detection sensor S5.

If a judgment in Step S22 is YES, namely, the wafer existence/nonexistence detection sensor S5 is OFF, because a wafer W is not loaded on the wafer loading section at the tip of the arm VR4, the wafer W can be unloaded from the buffer stage ST1 of one vacuum lock chamber VL1.

If a judgment in Step 22 is NO, an error occurs to issue an alarm.

As the causes of the error, temporary malfunction, failure or deviation of a mounting position of the wafer existence/nonexistence detection sensor S5, temporary malfunction of the controller CNT, defective operation of the cylinder VR3, temporary malfunction, failure or deviation of a mounting position of the cylinder stroke sensor, and the like are exemplified. If the alarm is issued, the vacuum carrying sequence is temporarily suspended, and an alarm display is displayed on the operation screen D1.

Thereafter, if the “retry” button is pressed on the operation screen D1, retry processing that the sequences after Step S26 where the error has occurred are re-repeated is executed.

The error caused by the temporary malfunction is cancelled to restore the system by the retry processing.

If the error can't be cancelled to restore the system by even the retry processing or an error cancellation can't be expected to restore the system from the viewpoint of contents and items of the error, the “forced termination” button is selected, abnormal termination processing that abnormally terminates the carrying sequence is executed.

In this case, as the errors, failure of the wafer existence/nonexistence detection sensor S5, defective operations of the cylinder VR3, failure or deviation of a mounting position in the cylinder stroke sensor, and the like are exemplified.

As the maintenance, replacement or modification of deviation of a mounting position in the wafer existence/nonexistence detection sensor S5, and repairing or replacement of the cylinder VR3 are performed.

If a judgment in Step 26 is YES or an error is cancelled to store the system by the retry processing, the sequence proceeds to Step S30.

In Step S30, the cylinder VR3 is extended further from the wafer existence/nonexistence detection position to the wafer unloading position, next, whether or not the wafer loading section at the tip of the arm is positioned at a wafer unloading position is judged by comparing a detected value of the cylinder stroke sensor that detects a stroke position of the cylinder VR3 with a set value (Step S31).

If a judgment result is NO, an error occurs to issue an alarm.

As the causes of the error, defective operation of the cylinder VR3 (abnormality of the mechanism that expands and contracts the cylinder VR3 or the circuit), temporary malfunction or deviation of a mounting position of the cylinder stroke sensor that detects expansion/contraction of the cylinder VR3 deviation of a mounting position of the cylinder VR3, and temporary malfunction of the controller CNT are exemplified.

If the alarm is issued, the vacuum carrying sequence is temporarily suspended (Step S32), and an alarm display is displayed on the operation screen D1 (Step S33).

If the “retry” button is subsequently pressed on the operation screen D1 (Step S34), the retry processing is executed.

If the error can't be cancelled to restore the system by the retry processing or an error cancellation can't be expected to restore the system by even the retry processing, the “forced termination” is pressed on the operation screen D1 (Step S34), abnormal termination processing that abnormally terminates the carrying sequence is executed, thereafter, the maintenance is executed.

As the causes of such errors, defective operation or deviation of a mounting position of the cylinder VR3 or failure or deviation of a mounting position of the cylinder stroke sensor that detects expansions/contractions of the cylinder VR3 are exemplified.

If the alarm is issued, the vacuum carrying sequence is temporarily suspended (Step S32), an alarm display is displayed on the operation screen D1 (Step S33).

If the “retry” button is subsequently pressed on the operation screen D1 (Step S34), the retry processing is executed.

As the maintenance, replacement of the cylinder stroke sensor, repairing or replacement of the cylinder VR3, and modifications of mounting position of the cylinder stroke sensor and cylinder VR3 are performed.

If a judgment in Step S31 is YES, namely, the wafer W can be unloaded by the wafer loading section at the tip of the arm VR4, the sequence proceeds to Step S35.

In Step S35, a height of the elevator EV is increased to a wafer W loading position, and the wafer W is loaded by the wafer loading section at the tip of the arm VR4.

Thereafter, whether or not an elevating position of the elevator EV is at a wafer loading position is judged by comparing a detected value of the elevating position detection sensor of the elevator EV with a set value in Step S36.

If a judgment result is NO, an error occurs to issue an alarm.

As the causes of the error, defective operation or failure of the elevator EV, malfunction, defective operations or deviation of a mounting position of the elevating position detection sensor that detects an elevating position of the elevator EV, temporary malfunction of the controller CNT, and the like are exemplified.

If the alarm is issued, the vacuum carrying sequence is temporarily suspended (Step S37), an alarm display is displayed on the operation screen D1 (Step S38).

Thereafter, the “retry” button is pressed on the operation screen D1 (Step S39), the retry processing is executed, and the processing after Step 35 that are the causes of the error occurrence are re-executed.

If the error can't be cancelled to restore the system by even the retry processing, the “forced termination” button is pressed on the operation screen D1 (Step S39), abnormal termination processing is executed.

After the abnormal termination is over, maintenance is executed.

As the causes of the error, defective operation or failure of the elevator EV, failure or deviation of a mounting position of the elevating position detection sensor, and the like are exemplified.

As the maintenance, repairing or replacement of the elevator EV, replacement or modification of deviation of a mounting position of the elevating position detection sensor are performed.

If a judgment result in Step S35 is YES or the error is cancelled to restore the system by the retry processing, the wafer loading sequence is normally terminated, and the sequence proceeds to the next wafer existence/nonexistence detection and wafer unloading sequence Sq4.

### (3-4) Wafer Existence/Nonexistence Detection and Wafer Unloading Sequence (Sq4)

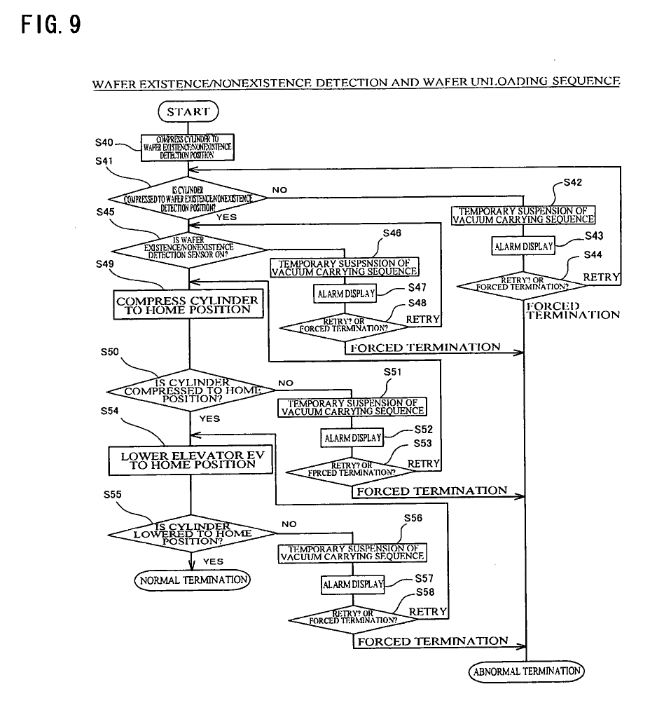

FIG. 9 shows one example of the wafer existence/nonexistence detection and wafer unloading sequence Sq4.

This sequence Sq4 is a sequence that loads the wafer W loaded on the substrate loading section in the arm VR4 from the vacuum lock chamber VL1 onto the vacuum carrying chamber TM.

First, the cylinder VR3 is contracted to the wafer detection position (Step S40), next, whether or not the cylinder VR3 is contracted to the wafer detection position is judged by the wafer loading section with ON, OFF of the wafer existence/nonexistence detection sensor S5 (Step S41). In this case, a judgment is done by comparing a detected value of the cylinder stroke sensor with a set value.

If a judgment result is NO, namely, the wafer W can't be detected, an error occurs to issue an alarm.

If the alarm is issued, the vacuum carrying sequence is temporarily suspended (Step S42), an alarm display is displayed on the operation screen D1 (Step S43).

As the causes of the error, failure of the cylinder VR3, deviation of a mounting position of the cylinder VR3, temporary malfunction or failure of the cylinder stroke sensor, temporary malfunction of the controller CNT, deviation of a mounting position of the cylinder stroke sensor, and the like are exemplified.

If the “retry” button is pressed on the operation screen D1 to process the error (Step S44), the retry processing is executed, and the processing after Step S40 that are the causes of the error are re-executed.

If the error can't be cancelled to restore the system by the retry processing or the error can't be cancelled to restore the system due to the item name or content of an error display with the retry processing, the “forced termination” button is pressed on the operation screen D1 (Step S44).

After the forced termination is over, maintenance is executed.

As the maintenance, repairing, replacement of the cylinder VR3, modification of deviation of a mounting position in the cylinder VR3, replacement of the cylinder stroke sensor or modification of deviation of a mounting position in the cylinder stroke sensor are performed.

If a judgment result in Step S41 is YES or the error is cancelled to restore the system by the retry processing, the sequence proceeds to the next Step S45.

In step S45, a wafer W existence/nonexistence is confirmed by ON, OFF of the wafer existence/nonexistence detection sensor S5.

If a judgment result is NO, an error occurs to issue an alarm.

If the alarm is issued, the vacuum carrying sequence is temporarily suspended (Step S46), an alarm display is displayed on the operation screen D1 (Step S47), and it is an instruction waiting from a maintenance worker.

As the causes of the error, there are temporary malfunction, failure or deviation of a mounting position of the wafer existence/nonexistence detection sensor S5, defective operation of the cylinder VR3, temporary malfunction, failure or deviation of a mounting position of the cylinder stroke sensor, temporary malfunction of the controller CNT, and the like.

If the “retry” button is pressed on the operation screen D1 by a maintenance worker (Step S48), the processing after Step S45 that are the causes of the error are re-executed. If an error occurs due to temporary malfunction of the wafer existence/nonexistence detection sensor S5 or stroke sensor, the error is cancelled to restore the system by the retry processing.

If the error can't be cancelled to restore the system by the retry processing or an error cancellation can't be expected to restore the system by even the retry processing, the “forced termination” button is pressed (Step S48), the carrying sequence is abnormally terminated.

After the abnormal termination is over, maintenance is executed.

As the maintenance, there are failure or deviation of a mounting position of the wafer existence/nonexistence detection sensor S5, replacement or modification of deviation of a mounting position of the stroke sensor, repairing or replacement of the cylinder VR3, and the like.

In this case, as the causes of the error, there are failure or deviation of a mounting position of the wafer existence/nonexistence detection sensor S1, defective operation of the cylinder VR3, failure or deviation of a mounting position of the cylinder stroke sensor, temporary malfunction of the controller CNT, and the like.

If a judgment result in Step S45 is YES or the error is cancelled to restore the system by the retry processing, the sequence proceeds to the next Step S49.

In Step S49, the cylinder VR3 is contracted to the home position, the wafer W is unloaded to the home position, in Step S50, whether or not the cylinder VR3 is returned to the home position is judged by comparing a detected value of the cylinder stroke sensor with a set value.

If a judgment result is NO, an error occurs to issue an alarm.

If the alarm is issued, the vacuum carrying sequence is temporarily suspended (Step S51), an alarm display is displayed on the operation screen D1.

As the causes of the error, temporary malfunction, deviation of a mounting position or failure of the cylinder stroke sensor, defective operation or failure of the cylinder VR3, temporary malfunction of the controller CNT, and the like are exemplified.

If the “retry” button is pressed on the operation screen D1 to process and confirm the error, the sequences after Step S49 where the error has occurred are re-executed.

If the error can't be cancelled to restore the system or an error cancellation can't be expected to restore the system with an alarm display by the retry processing, the “forced termination” button is pressed on the operation screen D1, and abnormal processing that abnormally terminates the carrying processing is executed.

In this case, as the errors, defective operations of the cylinder VR3, failure or deviation of a mounting position of the cylinder stroke sensor, and the like are exemplified.

If a judgment result in Step S49 is YES or the error is cancelled to restore the system with the retry processing, the sequence proceeds to Step S54.

In step S54, the elevator EV is lowered to the home position. Next, whether or not the elevator EV is already lowered to the home position is confirmed (Step S55).

In this case, a judgment is made by comparing a detected value of the elevating position sensor that detects an elevating of the elevator EV with a set value.

If a judgment result is NO, an error occurs to issue an alarm.

If the alarm is issued, the vacuum carrying sequence is temporarily suspended (Step S56), an alarm display is displayed on the operation screen D1 (Step S57).

Thereafter, it is an instruction waiting from a maintenance worker.

As the causes of the error, defective operation or failure of the elevator EV, temporary malfunction, defective operation or deviation of a mounting position of the elevating position detection sensor that detects an elevating position of the elevator EV, temporary malfunction of the controller CNT, and the like are exemplified.

If the “retry” button is pressed on the operation screen D1 to process and confirm the error, the retry processing is executed, and the sequences after Step S54 that are the causes of the error are re-executed.

If the error can't be cancelled to restore the system or an error cancellation can't be expected to restore the system by even the retry processing, the “forced termination” button is pressed on the operation screen D1, the carrying sequence is abnormally terminated. After the abnormal termination is over, maintenance is executed.

In this case, the causes of the error are narrowed to defective operation or failure of the elevator EV, failure or deviation of a mounting position of the elevating position detection sensor, and the like.

As the maintenance, repairing or replacement of the elevator EV, replacement or modification of deviation of a mounting position of the elevating position detection sensor are performed.

If a judgment result in Step S55 is YES or the error is cancelled to restore the system by the retry processing, a wafer existence/nonexistence detection and wafer unloading sequence Sq4 is terminated, and the sequence proceeds to the next wafer transferring sequence Sq5.

### (3-5) Wafer Transferring Sequence (Sq5)

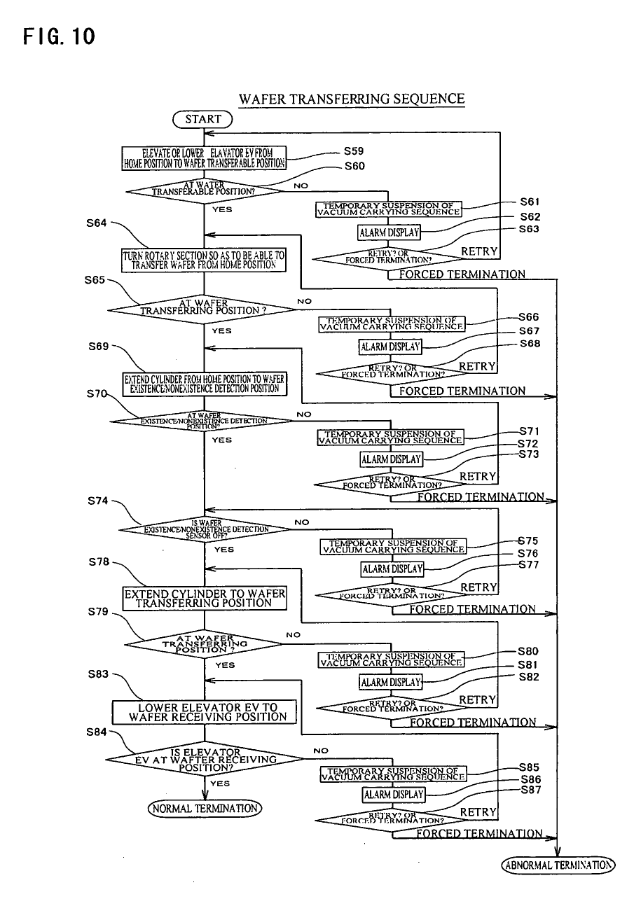

FIG. 10 shows one example of the wafer transferring sequence Sq5.

This sequence Sq5 is a sequence that carries a wafer W unloaded from the vacuum lock chamber VL1 to the process chamber PM1 by the vacuum side robot VR.

In this sequence Sq5, first, an elevating position of the vacuum side robot VR is controlled to a wafer W transferable position by elevating or lowering the elevator EV from its home position (Step 59).

Thereafter, whether or not an elevating position of the elevator EV is already at the wafer W transferable position is judged by comparing a detected value of the elevating position detection sensor (not illustrated) that detects the elevating position of the elevator EV with a set value (Step S60).

If a judgment result is NO, an error occurs to issue an alarm.

If the alarm is issued, the vacuum carrying sequence is temporarily suspended (Step S61), and an alarm display is displayed on the operation screen D1 of a monitor (Step S62).

As the causes of the error, temporary malfunction, failure or deviation of a mounting position of the elevating position detection sensor, defective operation or failure of the elevator EV, and the like are exemplified.

If the “retry” button is selected on the operation screen D1 to cancel the error to restore the system (Step S63), the retry processing is executed, the processing after Step S59 that are the causes of the error are re-executed.

If the error is cancelled to restore the system by the retry processing, an elevating position of the elevator EV is at the wafer W transferable position.

If the error is not cancelled to restore the system by even the retry processing or an error cancellation can't be expected to restore the system from the viewpoint of the content and item name of an alarm display, the “forced termination” button is pressed on the operation screen D1 (Step S63), and abnormal termination processing that forcedly terminates the vacuum carrying sequence is executed.

If the vacuum carrying sequence is abnormally terminated, maintenance that cancels the error is executed. As the maintenance, repairing or replacement of the elevator EV, and confirmation of a mounting position or modification of a mounting position of the elevating position detection sensor are performed.

If a judgment result in Step S60 is normal, the sequence proceeds to Step S64.

In Step S64, the rotary section VR5 of the vacuum side robot VR is turned from the home position to the wafer W transferable position.

Next, whether or not a turning angle of the rotary section VR5 is at a wafer transferable position is judged by comparing a detected turning angle of the rotary section VR5 detected by the rotational position detection sensor (not illustrated) provided at the rotary section VR 5 with a set turning angle (Step S65).

If a judgment result is NO, an error occurs to issue an alarm.

If the alarm is issued, the vacuum carrying processing is temporarily suspended (Step S66), an alarm display is displayed on the operation screen D1 (Step S67).

Thereafter, if the “retry” button is selected on the operation screen D1 (Step S68), the retry processing is executed, the processing after Step S64 that are the causes of the error are re-executed.

If the error can't be cancelled to restore the system or an error cancellation can't be expected to restore the system by even the retry processing, the “forced termination” button is pressed on the operation screen (Step S68), this allows abnormal termination processing that terminates the carrying sequence to be executed.

After the vacuum carrying sequence is abnormally terminated, maintenance that cancels the error to restore the system is executed.

As the maintenance, repairing or replacement of the rotary section VR5, and replacement or modification of a mounting position of the rotational position detection sensor are performed.

If a judgment result in Step S65 is YES or the error is cancelled to restore the system by the retry processing, the sequence proceeds to the next Step S69.

In Step S69, the cylinder VR3 of the vacuum side robot VR is extended from the home position to the wafer existence/nonexistence detection position to detect whether or not the wafer W is loaded on the wafer loading section of the arm VR4.

If an extension of the cylinder VR3 is finished, next, whether or not the wafer loading section at the tip of the arm VR4 is positioned at the wafer existence/nonexistence detection position that detects a wafer W existence/nonexistence is judged by comparing a detected value of the cylinder stroke sensor that detects an extended position of the cylinder VR3 with a set value (Step S70).

If a judgment result is NO, an error occurs to issue an alarm.

As the causes of the error, temporary malfunction of the cylinder stroke sensor, defective operation of the cylinder VR3, deviation of a stroke setting of the cylinder. VR3, failure or deviation of a mounting position of the cylinder stroke sensor, malfunction of the controller CNT, and the like are exemplified.

If the alarm is issued, the vacuum carrying sequence is temporarily suspended (Step S71), an alarm display is displayed on the operation screen D1 (Step S72).

If the “retry” button is pressed on the operation screen D1 (Step S73), the retry processing is executed, the processing after Step S69 that are the causes of the error are executed.

If a temporary error is cancelled to restore the system by the retry processing, the sequence proceeds to the next Step S74 on the supposition that the processing is normally terminated.

If the error can't be cancelled to restore the system by even the retry processing or an error cancellation can't be expected to restore the system from the viewpoint of the content or item name of an alarm display, the “forced termination” button is pressed on the operation screen D1 (Step S73), abnormal termination processing that terminates the carrying sequence is executed.

After the abnormal termination is over, maintenance is executed.

As the maintenance, replacement or repairing of the cylinder VR3, stroke re-setting of the cylinder VR3, replacement of the cylinder stroke sensor, and the like are performed.

If a judgment in Step S70 is YES, the wafer W is loaded on the wafer loading section at the tip of the arm VR4.

In Step S74, whether or not the wafer W is loaded on the wafer loading section at the tip of the arm VR4 is judged by ON, OFF of the wafer existence/nonexistence detection sensor S1.

If a judgment result is YES, namely, the wafer existence/nonexistence detection sensor S1 is OFF, an error occurs to issue an alarm.

If the alarm is issued, the vacuum carrying sequence is temporarily suspended (Step S75), an alarm display is displayed on the operation screen D1 (Step S76).

If the “retry” button is pressed on the operation screen D1 (Step S77), the retry processing is executed, and the processing after Step S74 that are the causes of the error are executed.

If an error is caused by temporary malfunction of the wafer existence/nonexistence detection sensor S1 or that of the controller CNT, the error may be cancelled to restore the system by the retry processing.

If the error can't be cancelled to restore the system or an error cancellation can't be expected to restore the system by even the retry processing, the “forced termination” button is pressed (Step S77), abnormal termination processing that forcedly terminates the carrying sequence is executed.

After the abnormal termination is over, maintenance is executed.

In this case, as the maintenance, replacement of the wafer existence/nonexistence detection sensor S1, repairing or replacement of the cylinder VR3, modification of a mounting position of the wafer existence/nonexistence detection sensor S1 or stroke sensor, position setting of the cylinder stroke sensor of the cylinder VR3, and the like are performed.

If a judgment in Step S74 is NO, namely, the wafer W is detected, the sequence proceeds to Step S78.

In Step S78, the cylinder VR3 is extended further from a wafer existence/nonexistence detection position to a wafer loading position. In the status, the wafer loading section at the tip of the arm VR4 is inserted into the process chamber PM1.

Next, whether or not a position of the wafer loading section at the arm tip is at a wafer loading position is judged by comparing a detected value of the cylinder stroke sensor that detects a stroke position of the cylinder VR3 with a set value (Step S79).

If a judgment result is NO, an error occurs to issue an alarm.

As the causes of the error, defective operation of the cylinder VR3, temporary malfunction or deviation of a mounting position of the cylinder stroke sensor that detects a expansion and contraction of the cylinder VR3, and the like are exemplified.

If the alarm is issued, the vacuum carrying sequence is temporarily suspended (Step S80), an alarm display is displayed on the operation screen D1 (Step S81).

If the “retry” button is pressed on the operation screen D1 (Step S82), the retry processing is executed.

If the error can't be cancelled to restore the system by even the retry processing or an error cancellation can't be expected to restore the system by even the retry processing, “the “forced termination” button is pressed on the operation screen D1 (Step S82), abnormal termination processing that abnormally terminates the carrying sequence is executed, thereafter, maintenance is executed.

As the maintenance, replacement of the cylinder stroke sensor, repairing or replacement of the cylinder VR3, modification of a mounting position of the cylinder stroke sensor, re-setting of a stroke of the cylinder VR3, and the like are performed.

If a judgment in Step S79 is YES, namely, the wafer loading at the tip of the arm VR4 is on the wafer loading section inside the process chamber PM1, or the error caused by malfunction is cancelled to restore the system by the retry processing, the sequence proceeds to Step S83.

In Step 83, the elevator EV is lowered to a receiving position of the process chamber PM1 (concretely, a receiving position to a susceptor). Next, whether or not a lowered position of the elevator EV is at a wafer transferring position is judged by comparing a detected value of the elevating position detection sensor in the elevator EV with a set value (Step S84).

If a judgment result is NO, an error occurs to issue an alarm. If the alarm is issued, the vacuum carrying sequence is temporarily suspended (Step S85), an alarm display is displayed on the operation screen D1 (Step 86).

Thereafter, if the “retry” button is pressed on the operation screen D1 (Step S87), the retry processing is executed, the sequences after Step S83 that are the causes of the error are re-executed.

As the causes of the error, defective operation, failure of the elevator EV, temporary malfunction or deviation of a mounting position of the elevating position detection sensor that detects an elevating position of the elevator EV, malfunction of the controller CNT, and the like are exemplified.

If the error is cancelled to restore the system by the retry processing, the transfer of the wafer W is finished.

If the error can't be cancelled to restore the system by even the retry processing, the “forced termination” button is pressed on the operation screen D1 (Step S87), abnormal termination processing is executed.

After the normal termination processing is over, maintenance is executed.

As the maintenance, repairing or replacement of the elevator EV, and replacement or modification of a mounting position of the elevating position detection sensor are performed.

If a judgment result in Step S84 is YES, the sequence proceeds to the next wafer existence/nonexistence confirmation sequence Sq6.

### (3-6) Wafer Existence/Nonexistence Confirmation Sequence (Sq6)

This sequence Sq6 is a sequence that confirms that the transfer of the wafer W is normally finished by detecting that there is no wafer W on the wafer loading section at the tip of the arm VR4 after the wafer W is carried to the process chamber PM1.

When comparing with the wafer existence/nonexistence detection and wafer unloading sequence Sq4, because a difference is only whether or not the wafer is loaded on the wafer loading section from the start to the end of the sequence, only the different points are described here with reference to FIG. 9.

In this sequence, because the premise is such that the wafer W is not loaded on the wafer loading section after the wafer W is transferred, in Step S45, the wafer existence/nonexistence detection sensor S1 is normal when it is OFF, and an error occurs to issue an alarm when it is ON. The cause of the error is also the same as in this example.

If the alarm is issued, the vacuum carrying sequence is temporarily suspended (Step S46), an alarm display is displayed on the operation screen D1 (S47).

If the “retry” button is pressed to process the error, the sequences after Step S45 that are the causes of the error are re-executed.

If the error can't be cancelled to restore the system or an error cancellation can't be expected to restore the system by the retry processing, the “abnormal termination” button is selected, abnormal termination processing that abnormally terminates the carrying sequence is executed to perform the maintenance. Because the other points are the same, the descriptions thereof are omitted.

### (3-7) Carrying Destination Gate Valve Closing Sequence (Sq7)

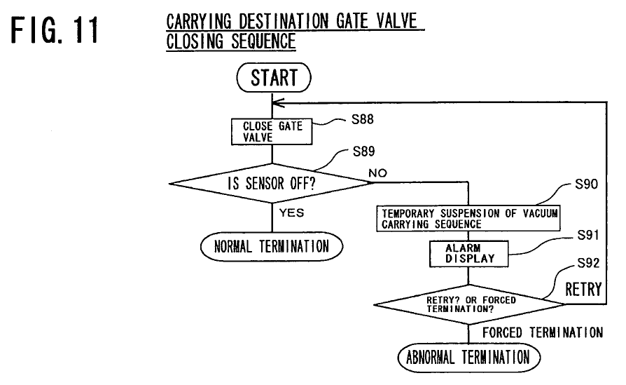

FIG. 11 shows one example of the carrying destination gate valve closing sequence Sq7.

This sequence Sq7 is a sequence that allows the wafer W to be processed in the process chamber PM1 by closing the gate valve G5 after the wafer W is carried into the process chamber PM1 that is the carrying destination.

In this sequence Sq7, first, the gate valve G5 of the process chamber PM1 is closed (Step S88), thereafter, whether or not the gate valve G5 is closed is confirmed by ON, OFF of the opening/closing sensor that detects of the opening/closing of the gate valve G5 (Step S89).

If a judgment result in Step S89 is NO, namely, the opening/closing sensor is OFF, an error occurs to issue an alarm.

As the causes of the error, temporary malfunction of the opening/closing sensor (not illustrated) of the gate valve G5 or the controller CNT, defective operation of the gate valve G5, and the like are exemplified.

If the alarm is issued, the vacuum carrying sequence is temporarily suspended (Step S90), an alarm display is displayed on the operation screen D1 (Step S91).

Thereafter, if the “retry” button is pressed on the operation screen D1, the retry processing where the sequences after Step S88 that are the causes of the error are re-executed is executed.

If the error is normally cancelled to restore the system by the retry processing, the processing is terminated (Normal termination).

If the error can't be cancelled to restore the system by even the retry processing, the “forced termination” button is selected on the operation screen D1 (Step S92), abnormal termination processing that abnormally terminates the carrying sequence is executed.

After the execution of the forced termination is over, maintenance such as replacement, modification of a mounting position of the opening/closing sensor of the gate valve G5 (not illustrated), or repairing or replacement of the gate valve G5 or G6 are performed.

### EFFECTS OF EMBODIMENTS

(1) According to the embodiment, unrequited maintenance can be removed because an error that can be cancelled to restore the system is cancelled to restore the system by the retry processing.

(2) Unrequired maintenance can be removed because whether or not an error is cancelled to restore the system by the retry processing is recognized.

(3) Even if an error that can't be cancelled to restore the system by the retry processing occurs, because the errors can be finally narrowed by the retry processing, it can shorten a time from the occurrence of an error to the restoration of the system.

(4) If a plurality of errors involved in the same part occurs in carrying sequences in series, the causes of the error can be sequentially narrowed from a relationship in consecutive errors. This allows a maintenance time to be shortened.

(5) If an error occurs in the carrying sequence, because the processing is suspended and the error is cancelled to restore the system, the quality of a wafer is not affected.

(6) Because the retry processing or abnormal termination processing is selected in accordance with the item name or content of an error in an alarm display, vain time can be eliminated.

(7) Even if an error occurs, the error may be cancelled to restore the system by the retry processing, the carrying sequence can continue. As a result, this allows mean time between failures (MTB) to be prolonged and operating efficiency in an apparatus to be improved.

(8) In addition, because there is an error to be cancelled to restore the system by the retry processing, as a result, the error is narrowed before maintenance is executed, labor such as part preparations can be largely reduced. This allows operating efficiency in an apparatus to be improved.

In the steps of the embodiment, “an error that is cancelled to restore the system by the retry processing is excluded from the object of the maintenance” is described above with regard to the narrowing of the errors. If an error occurs in a sequence using the same sensor and the same apparatus, respectively, basically, the same error as in the error executed in the maintenance of the previous sequence may be excluded from the object of the maintenance. If this is done so, because the errors are sequentially narrowed, it can largely reduce a time until the system is restored.

### DETAILED DESCRIPTION OF THE PREFERRED EMBODIMENTS

The preferred embodiments according to the present invention are also referred to below.

### Embodiment 1

Embodiment 1 is of a substrate processing apparatus including a processing chamber that processes a substrate, a carrier that carries the substrate, and a first controller that controls the carrier in accordance with a predetermined carrying sequence comprised of a plurality of sequences, wherein when an error occurs during carrying the substrate by the carrier, after the first controller temporarily suspends an execution of the carrying sequence, the first controller stops the processing upon receipt of the stop processing and re-executes the sequence that is the cause of the error occurrence out of the carrying sequences upon receipt of the retry processing.

### Embodiment 2

Embodiment 2 is of the substrate processing apparatus according to Embodiment 1 further including a second controller that controls to process the substrate in accordance with a predetermined processing sequence comprised of a plurality of steps, wherein when an error occurs during processing the substrate in the processing chamber, after the second controller temporarily suspends an execution of the processing sequence, the second controller stops the processing upon receipt of the stop processing and re-executes the step that is the cause of the error out of the processing sequences upon receipt of the retry processing.

### Embodiment 3

Embodiment 3 is of a substrate processing apparatus including a processing chamber that processes a substrate, a carrier that carries the substrate, and a second controller that controls to process the substrate in accordance with a predetermined carrying sequence comprised of a plurality of sequences, wherein when an error occurs processing the substrate in the processing chamber, after the second controller temporarily suspends an execution of the processing sequence, the second controller stops the processing upon receipt of the stop processing and re-executes the step that is the cause of the error out of the processing sequences upon receipt of the retry processing.

### Embodiment 4

Embodiment 4 is of a substrate processing apparatus including a substrate accommodating section that loads a substrate accommodating container that accommodates a plurality of substrates, an atmosphere carrying chamber that is communicated with the substrate accommodating container, a preliminary chamber that is communicated with the atmosphere carrying chamber and an inside of said preliminary chamber can be vacuum-exhausted, a substrate processing chamber that is communicated with the preliminary chamber and processes the substrate, an atmosphere carrier that carries the substrate between the substrate accommodating container and the preliminary chamber, a vacuum carrier that carries the substrate between the preliminary chamber and the substrate processing chamber, and a first controller that controls operations of the atmosphere carrier or the vacuum carrier in accordance with a predetermined carrying sequence comprised of a plurality of sequences, wherein when an error occurs during carrying the substrate by the atmosphere carrier or the vacuum carrier, after the first controller temporarily suspends an execution of the carrying sequence, the first controller stops the processing upon receipt of the stop processing and re-processes the sequence that is the cause of the error out of the carrying sequences.

### Embodiment 5

Embodiment 5 is of the substrate processing apparatus according to Embodiment 4 further including a second controller that controls to process the substrate in accordance with a predetermined processing sequence comprised of a plurality of steps, wherein when an error occurs during processing the substrate in the processing chamber, after the second controller temporarily suspends an execution of the processing sequence, the second controller stops the processing upon receipt of the stop processing and re-executes the step that is the cause of the error out of the processing sequences upon receipt of the retry processing.

### Embodiment 6

Embodiment 6 is of a substrate processing apparatus including a substrate accommodating section that loads a substrate accommodating container that accommodates a plurality of substrates, an atmosphere carrying chamber that is communicated with the substrate accommodating container, a preliminary chamber that is communicated with the atmosphere carrying chamber and an inside of said preliminary chamber can be vacuum-exhausted, a substrate processing chamber that is communicated with the preliminary chamber and processes the substrate, an atmosphere carrier that carries the substrate between the substrate accommodating container and the preliminary chamber, a vacuum carrier that carries the substrate between the preliminary chamber and the substrate processing chamber, a first controller that controls operations of the atmosphere carrier or the vacuum carrier in accordance with a predetermined carrying sequence composed of a plurality of sequences, and a second controller that controls to process the substrate in accordance with a predetermined processing sequence composed of a plurality of steps, wherein when an error occurs during processing the substrate in the processing chamber, after the second controller temporarily suspends an execution of the processing sequence, the second controller stops the processing upon receipt of the stop processing and re-executes the step that is the cause of the error out of the processing sequences upon receipt of the retry processing.

### Embodiment 7

Embodiment 7 provides a substrate processing apparatus including a processing chamber that processes a substrate, a carrier that carries the substrate, and a controller CNT that controls the carrier in accordance with a predetermined carrying sequences composed of a plurality of sequences, wherein when an error occurs during carrying the substrate (wafer) by the carrier, after the second controller temporarily suspends an execution of the carrying sequence, the second controller stops the processing upon receipt of the stop processing and re-executes the sequence that the cause of the error out of the carrying sequences upon receipt of the retry processing.

In Embodiment 7, the substrate is carried by the controller in accordance with a predetermined carrying sequences composed of a plurality of sequences by controlling the controller.

When the error occurs during carrying the substrate by the carrier, the controller temporarily suspends the carrying sequence. Thereafter, the sequence waits for an instruction for stop processing or retry processing, the controller re-executes the sequence that is the cause of the error upon receipt of the retry processing and stops the carrying sequence upon receipt of the stop processing.

### Embodiment 8

Embodiment 8 provides a substrate processing apparatus designed to be able to select the retry processing in each sequence in Embodiment 7.

If it is so designed, when an error occurs in all sequences comprised of the carrying sequences, the system thus designed allows the stop processing and retry processing to be selectively executed.

### Embodiment 9

Embodiment 9 provides a substrate processing apparatus configured such that the controller temporarily suspends an execution of the carrying sequence, and informs an operation screen of the error occurrence to allow the stop processing or the retry processing to be selected on the operation screen, if the controller is provided with the operation screen that receives a predetermined instruction (input) and an error occurs during carrying the substrate by the carrier in Embodiment 7.

The arrangement thus made allows an error occurrence to be clearly displayed on the operation screen. If the retry processing is selected first, because it can confirm whether or not an error can be cancelled to restore the system, the retry system may be first selected and the stop processing may be subsequently selected. In addition, in this case, if the name and content of an error are displayed on the operation screen including them in the information, it facilitates to prepare for maintenance.

### Embodiment 10

Embodiment 10 provides the substrate carrying method of a substrate processing apparatus having a step that temporarily suspends an execution of the carrying sequence and a step that executes a processing selected by awaiting a selection of stop processing that stops the carrying sequence or retry processing that executes the sequence that is the cause of the error out of the carrying sequences, when an error occurs during carrying the substrate by the carrier in the substrate carrying method of the substrate processing apparatus that carries the substrate by controlling the carrier in accordance with a predetermined carrying sequence composed of a plurality of sequences.

### Embodiment 11

Embodiment 11 provides the substrate carrying method of the substrate processing apparatus having a selection process that selects the stop processing or the retry processing in each sequence of the carrying sequences in Embodiment 10.

### Embodiment 12

Embodiment 12 provides the substrate carrying method of the substrate processing apparatus having a step that temporarily suspends an execution of the carrying sequence to allow the system to inform the operation screen of the error occurrence and select the stop processing or the retry processing on the operation screen, when an error occurs during carrying the substrate by the carrier in Embodiment 10.

### Another Embodiment

In addition, if an error occurs in the description of the Embodiment, the sequence is in status of selection waiting of either the “retry” button or the “forced termination” button. However, if two vacuum lock chambers are provided, even if an error occurs, a carrying tact may be controlled so as to allow wafer W carrying to continue using the other vacuum lock chamber.

This arrangement so made allows a substrate to be carried and processed without lowering the operation efficiency of the entire apparatus.

In addition, “when an error occurs in a carrying sequence, the error is cancelled to restore the system by executing the retry processing” is described in the Embodiment. However, errors other than the above-mentioned error may be cancelled to restore the system if the retry processing is repeated at least one time or more.

In addition, the vacuum carrying sequence is described in the Embodiment. However, it is natural that the present invention can be also applied to other sequences such as atmosphere carrying sequence.

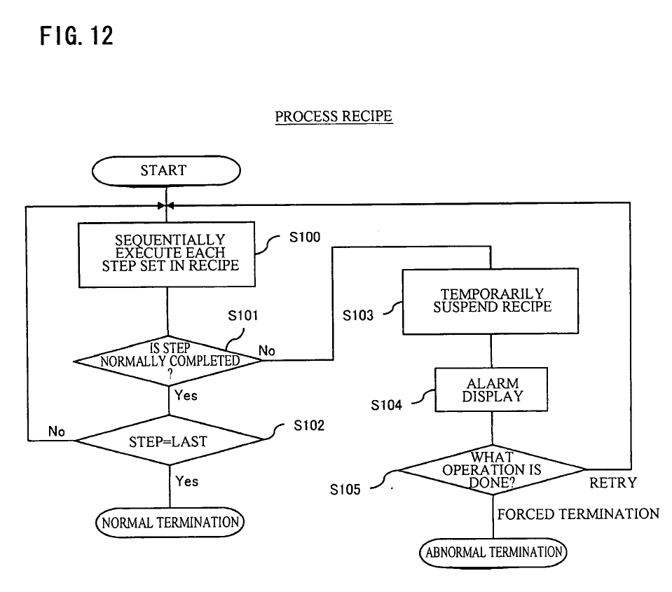

Here, the sequence of the process recipe is exemplified in FIG. 12. FIG. 12 exemplifies a sequence diagram of the process recipe of one embodiment according to the present invention having at least a step that controls a differential pressure between processing chambers where a wafer W is loaded (in process chambers PM1, PM2) and a carrying chamber or preliminary chamber (in vacuum carrying chamber TM or vacuum lock chambers VL1, VL2) (a substrate loading step), a step that controls the temperature/pressure of the processing chambers and the flows of gas that are fed into the processing chambers and the like (a process preparation step), a step that performs a predetermined processing on a wafer W in the processing chamber (a process step), and a step that controls differential pressures between the carrying chamber that unloads the processed wafer W or the preliminary chamber and the processing chambers (a substrate unloading step).

If the process recipe (a step processing) is started, the controller CNT sequentially executes the above-mentioned substrate loading step, process preparation step, process step, and a substrate unloading step (S100). Then, the controller CNT confirms whether or not the executions of each step are normally completed (S101), if normally completed (if “YES” in S101), it confirms whether or not the step is the last step (namely, whether or not it is the substrate unloading step) (S102). Then, if the step completely executed is the last step (substrate unloading step), (if “YES” in S102), the process recipe is normally terminated.

On the other hand, if the controller CNT is not normally completed due to the occurrences of any errors in the executions of each step (if “NO” in S101), it temporarily suspends an execution of the process recipe (a step processing) (S103), and displays an alarm display showing the reasons for errors on the operation screen D1 (S104). Then, if the “retry” button is pressed on the operation screen D1 (if branched to the “retry” processing in S105), the controller CNT re-executes (retry) the step where the error occurred. Then, if a temporary error is cancelled to restore the system by the retry processing, the sequence proceeds to the next step on the supposition that the processing is normally terminated.

If an error can't be cancelled to restore the system even if the retry processing is executed or an error cancellation can't be expected to restore the system due to the content or item name of an alarm display and the “forced termination” is pressed on the operation screen D1 (if branched to the “forced termination” in S105), the controller CNT executes abnormal termination processing that terminates the process recipe. After the completion of the abnormal termination processing is over, maintenance of the substrate processing apparatus is executed by an operator.

As in the Embodiment, in a substrate processing apparatus configured as, for example, a plasma asher apparatus and the like, an important subject is an improvement of processing efficiency (to shorten required time for the process recipe). On the contrary, in the substrate processing apparatus of the Embodiment, even if an error occurs during the executions of each step and the step is not normally completed, it is possible to execute retry processing on a step where an error occurs as required without forcedly setting a judgment waiting time of whether or not the error can be cancelled to restore the system. It can shorten the required time of a process recipe to improve processing efficiency in a substrate processing apparatus by executing retry processing in the substrate processing apparatus of the Embodiment, because there may be a case where an error is cancelled to quickly restore the system by retry processing to complete a step, depending upon the content of an error.

A maintenance worker judges whether or not retry processing should be executed in the above-mentioned carrying sequence or processing sequence. However, in the present invention of the patent application, the controller in the present invention of the patent application may be provided with a judging means that judges an execution of the retry processing in place of a case that a maintenance worker judges an execution of the retry processing like this. However, the Embodiment needs a provision that allows retry processing to be executed in response to an error that occurs. For example, it is a table (file) that standardizes the contents of errors and retry processing therefor. This error standardization table is beforehand stored in a memory section in the present invention of the patent application, and the controller judges to allow retry processing to be executed if an error occurs during the execution of the carrying sequence (or processing sequence). Then, for example, the number of the retry processing is set, and it is designed to abnormally terminate the processing if the number of the retry processing reaches a predetermined number as in the present invention of the patent application. In addition, the number of the retry processing may be changed by error.

Furthermore, when any error occurs during the execution of the carrying sequence or processing sequence and the retry processing is executed, apparatus operating efficiency is improved by informing a maintenance worker of what the error has occurred and the retry processing is executed, the error can be efficiently cancelled by what the maintenance worker prepares for possible maintenance in advance, thereby enabling the system to improve apparatus operating efficiency.

In addition, the semiconductor manufacturing apparatus is shown as one example of a substrate processing apparatus in the above-mentioned descriptions. However, it may be also an apparatus that processes glass substrate such as LCD apparatus, not limiting to a semiconductor manufacturing apparatus. In addition, the concrete contents of a substrate processing are not questioned, and may be not only deposition processing but also processing such as annealing processing, oxidation processing, nitriding processing, and diffusion processing.

In addition, the deposition processing may be, for example, also processing that forms CVD, PVD, oxide film, nitride film, and processing that forms a film containing metal.

In addition, the embodiment applied to a sheet-type substrate processing apparatus is described. However, this step can be used not only for a vertical-type substrate processing apparatus and a lateral-type substrate processing apparatus but also for other substrate processing apparatuses (stepper, lithographic apparatus, coating apparatus and the like) likewise in the Embodiment.

According to the present invention, if an error that occurs due to temporary malfunction is cancelled to restore the system by retry processing, an unrequired maintenance can be removed accordingly. In addition, even if the error is not cancelled to restore the system, a short-time repairing is possible because the cause of the error can be narrowed. This allows apparatus operating efficiency to be improved.

What is claimed is:

1. A substrate processing apparatus comprising:
a processing chamber that processes a substrate;
a carrier that carries the substrate; and
a first controller that controls the carrier in accordance with a predetermined carrying sequence composed of a plurality of sequences, wherein
when an error occurs during carrying the substrate by the carrier the substrate, after the first controller temporarily suspends an execution of the carrying sequence, the first controller stops the processing upon receipt of the stop processing and re-executes the sequence that is the cause of the error out of the carrying sequences upon receipt of the retry processing.

2. The substrate processing apparatus according to claim 1, further comprising;
a second controller that controls to process the substrate in accordance with a predetermined processing sequence composed of a plurality of steps, wherein
when an error occurs during processing the substrate in the processing chamber, after the second controller temporarily suspends an execution of the processing sequence, the second controller stops the processing upon receipt of the stop processing and re-executes the step that is the cause of the error out of the processing sequence upon receipt of the retry processing.

3. A substrate processing apparatus comprising:
a processing chamber that processes a substrate;
a carrier that carries the substrate;
a second controller that controls to process the substrate in accordance with a predetermined processing sequence composed of a plurality of sequences, wherein
when an error occurs during processing the substrate in the processing chamber, after the second controller temporarily suspends an execution of the processing sequence, the second controller stops the processing upon receipt of the stop processing and re-executes the step that is the cause of the error out of the processing sequence upon receipt of the retry processing.

4. A substrate processing apparatus comprising:
a substrate accommodating section that loads a substrate accommodating container that accommodates a plurality of substrates;
an atmosphere carrying chamber that is communicated with the substrate accommodating container;
a preliminary chamber that is communicated with the atmosphere carrying chamber and an inside of said preliminary chamber can be vacuum-exhausted;
a substrate processing chamber that is communicated with the preliminary chamber and processes each substrate;
an atmosphere carrier that carries the substrate between the substrate accommodating chamber and the preliminary chamber;
a vacuum carrier that carries the substrate between the preliminary chamber and the substrate processing chamber; and
a first controller that controls an operation of the atmosphere carrier or the vacuum carrier in accordance with a predetermined carrying sequence composed of a plurality of sequences, wherein
when an error occurs during carrying the substrate by the atmosphere carrier or the vacuum carrier, after the first controller temporarily suspends an execution of the carrying sequence, the first controller stops the processing upon receipt of the stop processing and re-executes the sequence that is the cause of the error out of the carrying sequence upon receipt of the retry processing.

5. The substrate processing apparatus according to claim 4, further comprising:
a second controller that controls to process the substrate in accordance with a predetermined processing sequence composed of a plurality of steps, wherein
when an error occurs during processing the substrate in the processing chamber, after the second controller temporarily suspends an execution of the carrying sequences, the second controller stops the processing upon receipt of the stop processing and re-executes the step that is the cause of the error out of the processing sequences upon receipt of the retry processing.

6. A substrate processing apparatus comprising:
a substrate accommodating section that loads a substrate accommodating container that accommodates a plurality of substrates;
an atmosphere carrying chamber that is communicated with the substrate accommodating container;
a preliminary chamber that is communicated with the atmosphere chamber and an inside of said preliminary chamber is vacuum-exhausted;
a substrate processing chamber that is communicated with the preliminary chamber and processes the substrate;
an atmosphere carrier that carries the substrate between the substrate accommodating chamber and the preliminary chamber;
a vacuum carrier that carries the substrate between the preliminary chamber and the substrate processing chamber;
a first controller that controls an operation of the atmosphere carrier or the vacuum carrying chamber in accordance with a predetermined processing sequence composed of a plurality of sequences; and
a second controller that controls to process the substrate in accordance with a predetermined processing sequence composed of a plurality of steps, wherein
when an error occurs during processing the substrate in the processing chamber, after the second controller temporarily suspends an execution of the processing sequence, the second controller stops the processing upon receipt of the stop processing and re-executes the step that is the cause of the error out of the processing sequence upon receipt of the retry processing.
